(19) United States
(12) Patent Application Publication
(10) Pub. No.: US 2017/0010325 A1
(43) Pub. Date: Jan. 12, 2017

(54) ADAPTIVE TEST TIME REDUCTION

(71) Applicant: QUALCOMM Incorporated, San Diego, CA (US)

(72) Inventors: Arul Subbarayan, San Diego, CA (US); Sachin Badole, Bangalore (IN); Archana Matta, San Diego, CA (US); Madhura Hegde, Bangalore (IN); Sergio Mier, San Diego, CA (US); Shankarnarayan Bhat, Bangalore (IN); Michael Laisne, Encinitas, CA (US); Glenn Mark Plowman, San Diego, CA (US); Prakash Krishnan, San Diego, CA (US)

(21) Appl. No.: 14/794,635

(22) Filed: Jul. 8, 2015

(51) Int. Cl. G01R 31/317

(52) U.S. Cl. CPC G01R 31/31707; G01R 31/31718

(57) ABSTRACT

A method and apparatus for adaptive test time reduction is provided. The method begins with running a predetermined number of structural tests on wafers or electronic chips. Pass/fail data is collected once the predetermined number of structural tests have been run. This pass/fail data is then used to determine which of the predetermined number of structural tests are consistently passed. The consistently passed tests are then grouped into slices within the test vectors. Once the grouping has been performed, the consistently passed tests are skipped when testing future production lots of the wafers or electronic chips. A sampling rate may be modulated if it is determined that adjustments in the tests performed are needed. In addition, a complement of the tests performed on the wafers may be performed on the electronic chips to ensure complete test coverage.

### FIELD

The present disclosure relates generally to wireless communication systems, and more particularly to a method and apparatus for adaptive test time reduction.

### BACKGROUND

Wireless communication devices have become smaller and more powerful as well as more capable. Increasingly users rely on wireless communication devices for mobile phone use as well as email and Internet access. At the same time, devices have become smaller in size. Devices such as cellular telephones, personal digital assistants (PDAs), laptop computers, and other similar devices provide reliable service with expanded coverage areas. Such devices may be referred to as mobile stations, stations, access terminals, user terminals, subscriber units, user equipment, and similar terms. These wireless devices rely on SoCs to provide much of the functionality desired by users.

SoCs are tested prior to assembly in wireless devices to ensure that the chip functions as desired within specified operating parameters. Testing SoCs may rely on design for test (DFT), which is a process that incorporates rules, and techniques for testing into the design of the chip to facilitate testing prior to delivery. DFT may be used to manage test complexity, minimize development time and reduce manufacturing costs. Testing involves two major aspects: control and observation. When testing any system or device it is necessary to put the system into a known state, supply known input data (the test data) and then observe the system or chip to ascertain if it performs as designed. Other integrated circuit (IC) devices require similar testing, and embodiments described herein also apply to testing electronic chips, or ICs.

Designers and manufacturers usually test various functions to validate the design. In addition, testing is performed on the wafers as well as the individual chips. A wafer is a larger substrate with multiple chip patterns placed on it. The wafer is separated into the individual chips or SoCs after wafer testing. The individual chip patterns are then separated and fabricated further to create individual devices. The individual chips are then tested for device performance. Often manufacturing engineers and customer engineers subject a chip design to a variety of test criteria to determine if the ideas in the design work in practice. This validation is especially important for SoCs, which involve a unique set of problems that challenge test procedures. Although high-density modern circuits, higher device speeds, surface-mount packaging, and complex board interconnect technologies have had a positive influence on state-of-the-art electronic systems, these factors have also greatly increased test complexity and cost. The cost for detecting and identifying faults using traditional test methods increases by an order of magnitude as circuit complexity increases. These increased costs and development time may delay product introduction and reduce time-to-market windows.

Current structural tests take up approximately thirty percent of the total test time at the wafer sort level as well as the final test or package test. The wafers must be screened and then the individual packaged parts must be screened. In many cases, a production run may include millions of wafers, and even more individual chips. There is a need in the art for a method to efficiently screen for defects while maintaining product quality.

### SUMMARY

Embodiments described herein provide a method for adaptive test time reduction. The method begins with running a predetermined number of structural tests on wafers or electronic chips. Pass/fail data is collected once the predetermined number of structural tests have been run. This pass/fail data is then used to determine which of the predetermined number of structural tests are consistently passed. The consistently passed tests are then grouped into slices within the test vectors. Once the grouping has been performed, the consistently passed tests are skipped when testing future production lots of the wafers or electronic chips. A sampling rate may be modulated if it is determined that adjustments in the tests performed are needed. In addition, a complement of the tests performed on the wafers may be performed on the electronic chips to ensure complete test coverage.

A further embodiment provides an apparatus comprising: means for running a predetermined number of structural tests on multiple production lots of electronic components; means for collecting pass/fail data for the predetermined number of structural test into slices within test vectors; means for skipping the consistently passed structural tests when testing future production lots of electronic components; and means for performing only those structural tests that produce failures.

A still further embodiment provides a computer-readable medium containing instructions, which when executed, cause a processor to perform the following steps: running a predetermined number of structural tests on multiple production lots of electronic components; collecting pass/fail data for the predetermined number of structural test into slices within test vectors; skipping the consistently passed structural tests when testing future production lots of electronic components; and performing only those structural tests that produce failures.

### BRIEF DESCRIPTION OF THE DRAWINGS

FIG. 1 illustrates vector slicing to identify tests vectors, in accordance with embodiments described herein.

FIG. 2 depicts pattern slicing for test time reduction in accordance with embodiments described herein.

FIG. 3 shows a snapshot of a “burst” with multiple slices, in accordance with embodiments described herein.

FIG. 4 illustrates test time reduction through vector slicing, in accordance with embodiments described herein.

FIG. 5 shows a sample history and yield results over multiple lots, in accordance with embodiments described herein.

FIG. 6 depicts risk mitigation for a test time reduction method, in accordance with embodiments described herein.

FIG. 7 shows an interaction model between operations testing and automatic test equipment, in accordance with embodiments described herein.

FIG. 8 illustrates a further interaction model between operational testing and automatic test equipment, in accordance with embodiments described herein.

FIG. 9 depicts enabling slices based on test results, in accordance with embodiments described herein.

FIG. 10 is a flowchart of a method of test flow implementation at the wafer sort level, in accordance with embodiments described herein.

FIG. 11 is a flowchart of a method of test flow implementation at the final test level, in accordance with embodiments described herein.

FIG. 12 is a flow diagram of an interaction model for a method of test time reduction in accordance with embodiments described herein.

### DETAILED DESCRIPTION

The detailed description set forth below in connection with the appended drawings is intended as a description of exemplary embodiments of the present invention and is not intended to represent the only embodiments in which the present invention can be practiced. The term “exemplary” used throughout this description means “serving as an example, instance, or illustration,” and should not necessarily be construed as preferred or advantageous over other exemplary embodiments. The detailed description includes specific details for the purpose of providing a thorough understanding of the exemplary embodiments of the invention. It will be apparent to those skilled in the art that the exemplary embodiments of the invention may be practiced without these specific details. In some instances, well-known structures and devices are shown in block diagram form in order to avoid obscuring the novelty of the exemplary embodiments presented herein.

As used in this application, the terms “component,” “module,” “system,” and the like are intended to refer to a computer-related entity, either hardware, firmware, a combination of hardware and software, software, or software in execution. For example, a component may be, but is not limited to being, a process running on a processor, an integrated circuit, a processor, an object, an executable, a thread of execution, a program, and/or a computer. By way of illustration, both an application running on a computing device and the computing device can be a component. One or more components can reside within a process and/or thread of execution and a component may be localized on one computer and/or distributed between two or more computers. In addition, these components can execute from various computer readable media having various data structures stored thereon. The components may communicate by way of local and/or remote processes such as in accordance with a signal having one or more data packets (e.g., data from one component interacting with another component in a local system, distributed system, and/or across a network, such as the Internet, with other systems by way of the signal).

Moreover, various aspects or features described herein may be implemented as a method, apparatus, or article of manufacture using standard programming and/or engineering techniques. The term “article of manufacture” as used herein is intended to encompass a computer program accessible from any computer-readable device, carrier, or media. For example, computer readable media can include but are not limited to magnetic storage devices (e.g., hard disk, floppy disk, magnetic strips . . . ), optical disks (e.g., compact disk (CD), digital versatile disk (DVD) . . . ), smart cards, and flash memory devices (e.g., card, stick, key drive . . . ), and integrated circuits such as read-only memories, programmable read-only memories, and electrically erasable programmable read-only memories.

Various aspects will be presented in terms of systems that may include a number of devices, components, modules, and the like. It is to be understood and appreciated that the various systems may include additional devices, components, modules, etc. and/or may not include all of the devices, components, modules etc. discussed in connection with the figures. A combination of these approaches may also be used.

Other aspects, as well as features and advantages of various aspects, of the present invention will become apparent to those of skill in the art through consideration of the ensuring description, the accompanying drawings and the appended claims.

Electronic devices are produced using wafers, a substrate patterned with multiple patterns for individual devices. Wafer fabrication lays down traces in a substrate and provides pads for additional components to be added to the individual devices. The individual device patterns may also include pads for eventual installation onto a printed circuit board or other similar electronic assembly. Wafers are tested before being separated into the individual devices to ensure that the time and expense of populating the devices is performed only on substrates that are properly fabricated. Improper or defective fabrication may result in broken pads or traces, and an individual device that will not function according to the specification.

Testing electronic chips requires planning for testing the chip as the chip is being designed. This may mean integrating testing pins and interfaces into the device so that test signals or built-in self-test (BIST) tests may be performed without probing the chip. This testing uses a test clock to route signals through cores of a chip and recording the results. The test clock circuit includes a core clock circuit, a pad clock circuit, and a test clock circuit among others. The core clock circuit generates a core clock signal enabling full speed operation of the core circuitry of the IC during test mode. The pad clock circuit generates a preliminary clock signal suitable for normal operation, and the test clock circuit generates a test clock signal suitable for operating the input/output (I/O) interface logic while in test mode.

This testing is usually carried out by inserting the IC to be tested, or device under test (DUT) into a test fixture, which simulates and monitors the I/O signals of the chip or IC to determine if the IC is functioning properly. For a microprocessor, the tester may generate and monitor all of the I/O signals needed to interface the IC to other components it must operate in conjunction with. For most IC devices currently in use, the frequency at which the microprocessor operates is a multiple of the frequency of the bus clock frequency provided by the tester. Provisions may need to be made when designing the IC to enable the core logic to operate at full speed during testing. Typically, this involves providing clock frequency ratio values that are enabled only during testing. A multiplier may be used to increase the internal clock speed for testing purposes. This may result in multiple clocks running simultaneously.

During testing test, data is scanned in to simulate internal system nodes within the IC while the IC is loaded in the test system. During the same scan, the previous condition of each node in the scan chain is scanned out. Samples are taken on the rising edge of the test clock. Testing mode selection and test data inspect values are sampled on the rising edge of the test clock, and the test data output data is sampled on the falling edge of the clock.

Testing is designed to handle three specific types of faults: stuck at fault test, transition delay fault, and path delay fault. A device with one of these faults may be said to have failed a structural test. A fault is a design failure or flaw that causes an incorrect response to input stimuli. When the test data is output, the values do not match the values of a correctly functioning IC or other electronic device. The stuck at fault test represents a failure model where a gate pin is stuck either open or closed. A closed gate indicates a short. A fault simulator uses fault models to represent a node shorted to ground, compared with a fault free circuit. An open gate is shorted to power. By faulting all of the nodes in the circuit the fault simulator produces the test pattern fault coverage.

The stuck at fault test is run using a slow speed clock and the entire IC is tested. In this test, both shifting in of test values and capture, or shifting out test values, use a slow pad clock. During the stuck at fault test all of the scan chains toggle at the same time irrespective of clock domains, voltage domains, or power domains. Scan chains allow every flip-flop in an IC to be monitored for particular parameters. For many SoCs the typical speed of the slow pad clock ranges from 25 MHz to 100 MHz, depending on the specific test fixture.

Transition delay faults cause errors in the functioning of a circuit based on its timing. These faults are caused by the finite rise and fall times of the signals in the gates and by the propagation delay of interconnects between the gates. Circuit timing should be carefully evaluated to avoid this type of error. Transition delay testing may also be used to determine the proper clock frequency of the circuit for correct functionality. Transition delay faults are caused by the finite time it takes for a gate input to show up at the output. If the signals are not given time to settle, a transition delay fault may appear. A challenge in testing is distinguishing between a delay fault, where the output yields the correct result, and an actual fault in the circuit. Tests may be developed to distinguish between slow to rise and slow to fall situations.

Transition delay fault testing use a slow pad clock for shifting values into and out of the flip-flops in the circuit. Capture uses a high-speed clock. Each clock domain is tested separately, and may use the same timing. Transition delay tests are performed for all the logic on the chip.

The path delay fault test looks at the longest path in the circuit and determines the effect on circuit timing. The longest path is typically determined based on the results of static timing analysis of the chip. In static timing analysis the expected timing of a digital circuit is determined without simulation. Once the longest path or critical path has been determined, path delay fault testing may be performed. In path delay fault testing shifting data is performed using a slow pad clock while data capture uses a high-speed clock. Each clock domain is tested separately.

A typical SoC has a core using at least one clock, and many have multiple clocks. Multiple clocks may be used in a SoC to limit the power used by the chip. The multiple clocks as well as every core on the chip use a different frequency. Most of the clocks are gated and are only un-gated when the clock is being used. As a result, at any given time the majority of flip-flops on the SoC are either clock gates or the domains are power collapsed during actual functional operation.

The power delivery network supplies power to all of the logic gates on the SoC or chip. Testing is a unique situation for the SoC, as during DFT mode operation all of the clock domains are on and during shift operations all of the flip-flops are toggling at their respective functional frequencies. Only during testing are all cores of the SoC on as most of the clocks are gated in normal operation and are only un-gated when in use. This operation results in increased heat being generated, and this heat affects SoC or chip operation. This thermal loading may cause false failures due to the heat generated. To cope with the heat loading it may be necessary to lower the shift frequency and stagger to capture of the domains to isolate these false failures. This causes increased testing time.

All of the testing described above is performed for each individual device. As wireless and other personal electronic devices have grown in use and popularity, the number of chips needed has grown astronomically. Many electronic devices use chips that may be programmed to perform specific functions when installed in the end use device. As a result, chips are produced in very large production lots and multiple tests on both the wafers and the individual chips are performed. Over time, the plethora of tests may begin to show a pattern of passing and failing tests, thus generating a defect density for the chip in question. This is particularly true for mature silicon products. A statistical confidence model may be developed that quantifies which tests are passed and at what level.

Embodiments described below provide a method for screening wafers and individual chip devices by selecting tests that identify failures and ignoring the tests that always or nearly always produce pass results. Once this data is available, further testing may be conducted based on a statistical model to provide a quantification of the escape rate. The consistently passing tests may then be grouped together. The remaining tests, those which disclose failures, are statistically analyzed. Rejected oriented analysis is then used to determine the series of tests that identify the defects causing rejection. By managing the tests that are enabled, the defect rate may still be correctly identified. This method provides an optimal balance between test time and defect screening. Effective coverage may be provided across varying voltages by enabling different tests.

Testing involves automatic test pattern generation for structural testing. These tests are typically run in the scan mode and no concurrent testing is allowed with other test blocks. In addition, the speed may be limited to 40 MHz. System level testing defective parts per million rate requirements may dictate that additional transition delay fault and path delay fault tests be run, causing a further increase in test time. All of the tests are typically run at a test suite level, with specific rules for bypassing test suites specified for a given test flow. Embodiments described below provide a method for recommending specific tests or “slices” of tests be run inside a “burst” of multiple slices, and further recommending slices within the burst that may be bypassed.

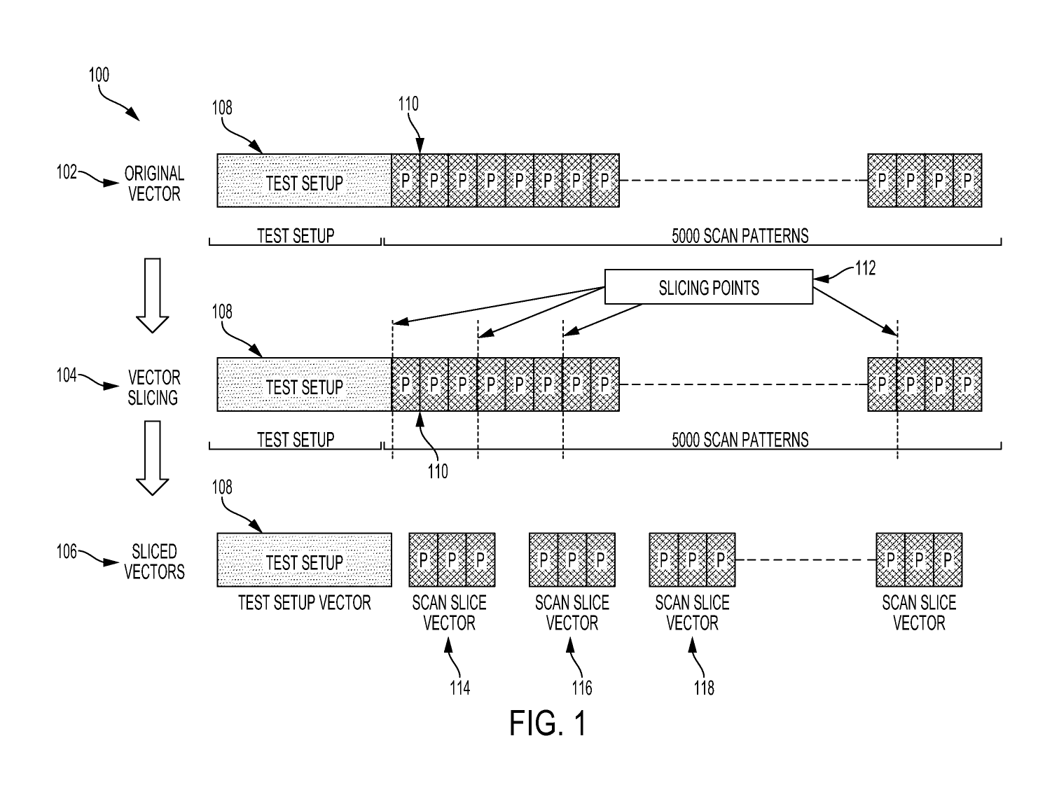

FIG. 1 provides an overview of how automatic test pattern generation vector slicing may be performed. The system level testing 100 is shown as including an original test vector 102. This original test vector 102 includes a test setup 108, and individual test scan patterns 110. This original test vector 102 is typically planned at the system test integration level and may require as many as 5000 scan patterns be performed. In contrast, test vectors may be generated using the vector slicing method described in embodiments below.

The vector slicing 104 results in grouping tests that are always passed. The vector slicing 104 includes test setup 108. The tests are then grouped into tests that are always passed, which are designated using slicing points 112. The individual test scan patterns 110 are grouped using the slicing points 112. The result is sliced vectors 106. Sliced vectors 106 include test setup 108 and scan slice vectors 114, 116, 118, and so on. The remaining tests, those the disclose failures are then statistically analyzed. Reject oriented analysis is used to determine the series of tests that identify the defects causing rejection. Only these tests are run, with the same set of tests run across all required voltages. Normally, three voltages, high, medium, and low are run.

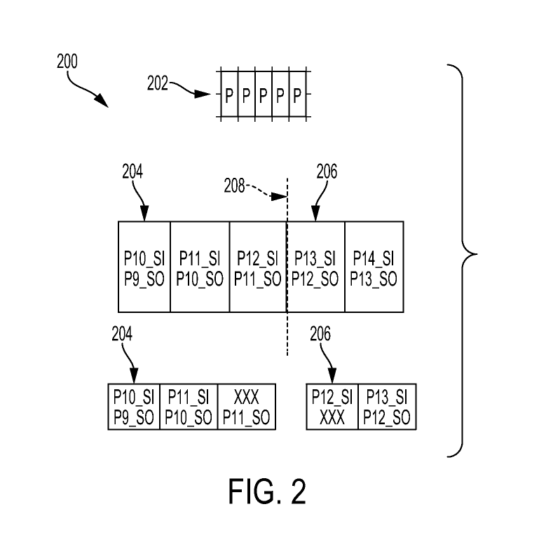

FIG. 2 provides a more detailed view of automatic test pattern generation pattern slicing. A test vector 200 includes tests 202. Slicing point 208 separates the tests into test slices 204 and 206. However, the transition patterns at the slicing point must be massaged for a smooth testing transition between tests 204 and 206. One pattern per slice is broken to perform an adjustment. This causes one additional shift to appear due to the slicing mechanism. As the slice operation is performed at the system test integration level, there is no setup pattern overhead for each sliced vector. Test pattern slices 204 and 206 may be performed in any order as long as the test setup slice is the first vector performed. This optional pattern slicing operation may be implemented at both the wafer sort level testing and the final or package testing levels.

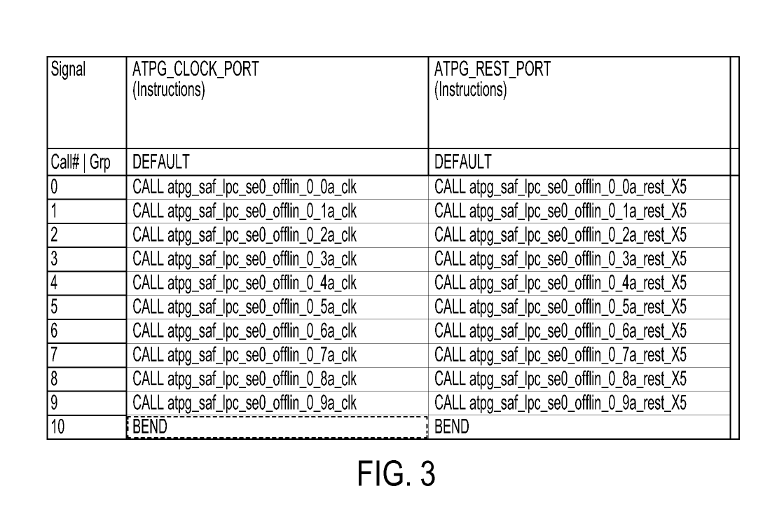

FIG. 3 illustrates how a single test vector of 5000 slices may be broken into many slices. These slices may be added to the test flow as a burst that calls the individual slices. A sample snapshot of a burst with ten slices is shown in FIG. 3.

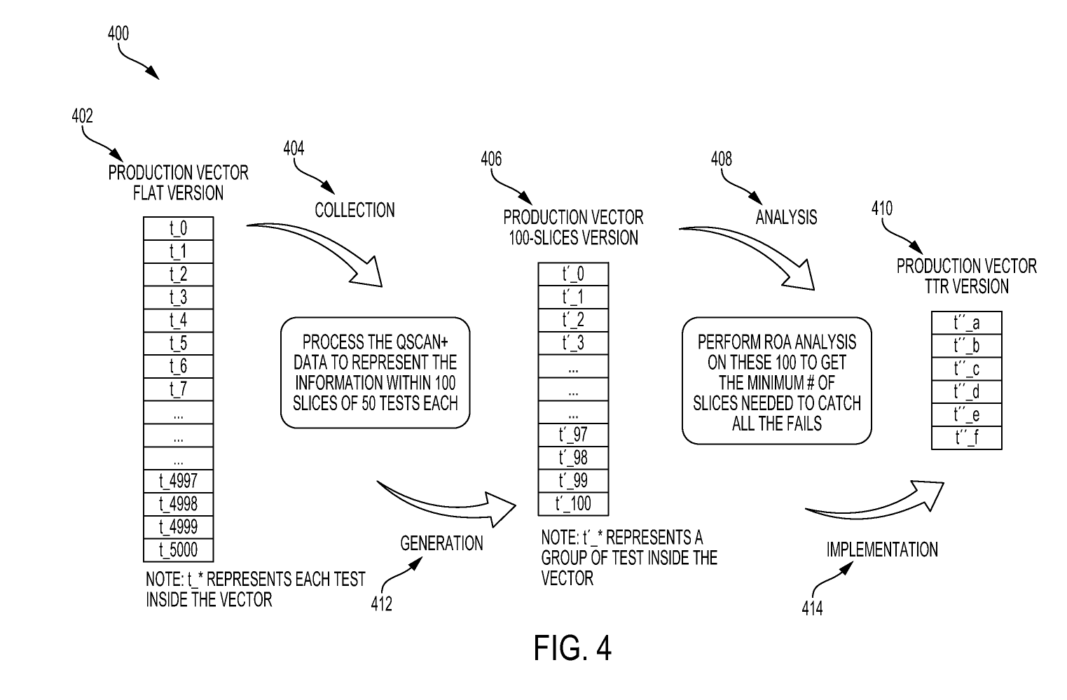

FIG. 4 gives a process overview of the above steps. The process 400 begins with production test vector 402 with multiple tests inside production test vector 402. At 404, the scan data from the structural tests in process and represent the information from multiple slices with multiple tests within each slice. As an example, in the collection step 404 processes the scan data using 100 slices with 50 tests in each slice. A generation step 412 results in production test vector 406. Production test vector 406 includes 100 slices. Production test vector 406 is run and then analyzed at 408. The analysis uses a reject-oriented analysis on the 100 slices of production test vector 406 to determine the minimum number of slices needed to identify all failures. This analysis 408 is implemented at 414, resulting in test time reduction test vector 410.

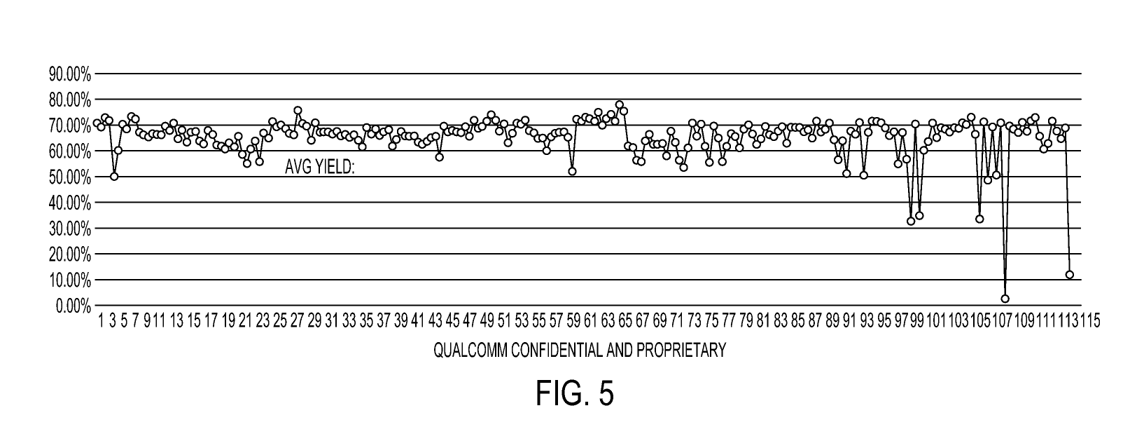

FIG. 5 depicts a sample yield rate across 23 lots containing 229 wafers. The testing is performed at three voltage levels, high, medium or nominal, and low voltage. At high voltage, the minimum number of slices needed to catch all failures was 60 out of 100 slices, a 40% time savings. At nominal voltage, 68 slices out of 100 were needed to catch all failures, a 32% savings. At low voltage, 76 test slices out of 100 were needed to catch all failures, a 24% savings. Other devices and testing programs may demonstrate different results.

Risk mitigation may be performed to modulate the sampling rate. The sample test rate may be varied so that the non-failure generating tests are performed on a periodic basis. The sample varying may be performed dynamically and minimizes the risk of inadvertently passing a defective die.

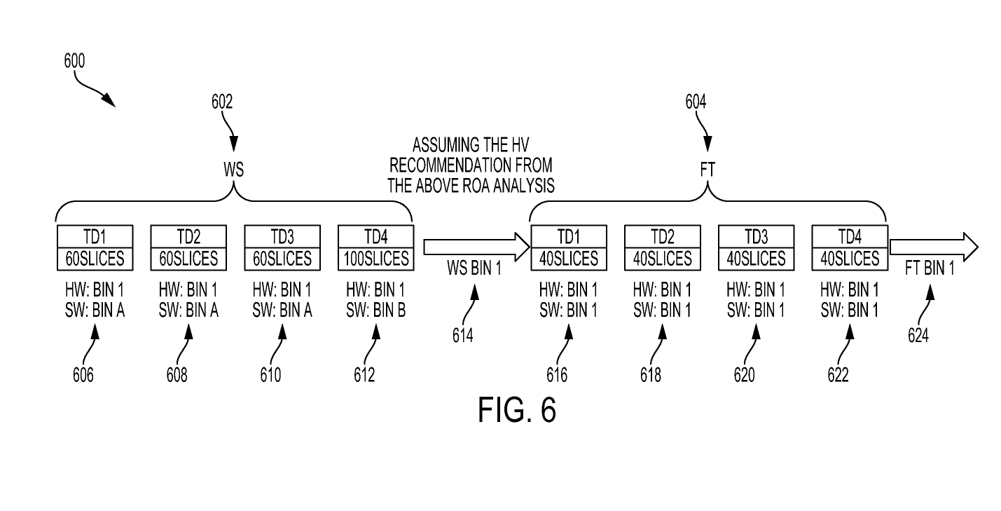

FIG. 6 illustrates a mechanism for risk mitigation. The risk is that some defects could “escape” as not all of the tests are being performed. More specifically, the risk is that a failure would have occurred in one of the tests that is consistently passed or always passed. As one example, there could be a potential 200 defects per million, or 0.02% across five wafers if there is a failure detected from the non-recommended set. Risk mitigation involves modulating the sampling rate based on process and design maturity. In these cases, the coverage at final or product test can be covered for 100% of the devices. In FIG. 6, the process 600 includes both wafer test (WS) and final test (FT). In WS 602 60 slices may be performed on test devices 606, 608, and 610, with 100 slices performed on test device 612. This assumes that the high voltage test is performed. The passing wafers are placed in WS bin 1 at step 614. These passing wafers continue on the FT 604. In FT 604 40 slices are performed for test devices 616, 618, 620 and 622. The passing devices are placed in FT bin 1 624. This risk mitigation process guarantees that all Bin 614 die from WS 602 will have been screen with the full set of automated test pattern generation tests when those devices reach Bin 1 status after FT. The 60 slices at WS 602 combined with the 40 slices at FT 604 total 100 slices, thus providing total coverage. This results in a double test time reduction with approximately 25% test time reduction occurring at WS 602 and an additional test time reduction of approximately 30% occurring at FT 604. Once the target yield rate is achieved, then testing may return to a reduced testing rate. In many cases, the risk is acceptable as the failure rate is low.

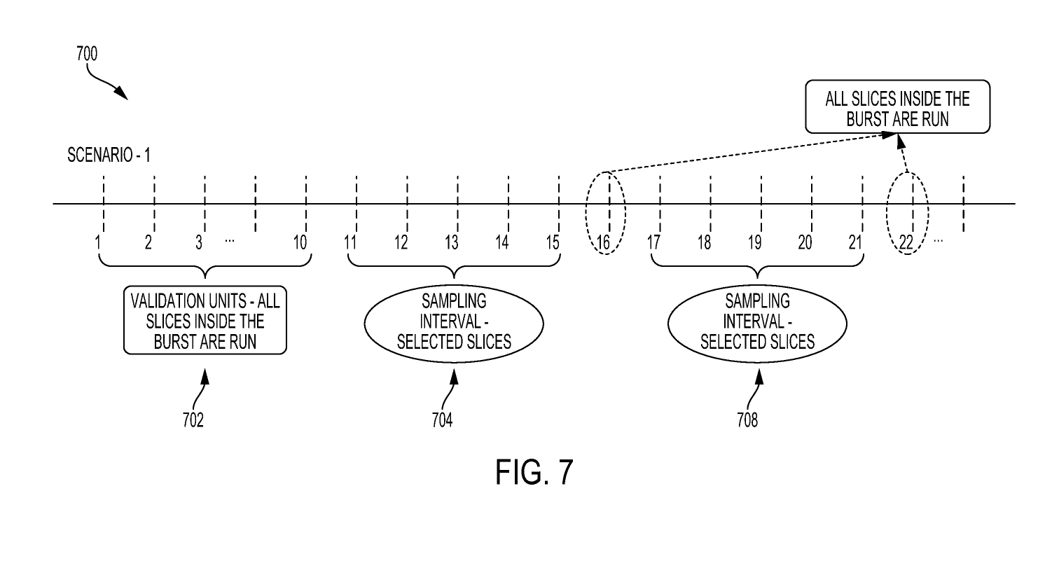

FIG. 7 depicts an interaction model between operational testing and automated test equipment. The scenario 700 begins when validation units 702 are tested. In the validation step 702 all slices inside the burst are run. At sampling interval 704 selected samples are tested, and this testing may include tests usually passed. After sampling interval 704 at process step 16 all slices inside a burst are run. In a further sampling interval 708 samples from selected slices are tested. At step 22, an additional burst test period occurs with all slices inside the burst being run.

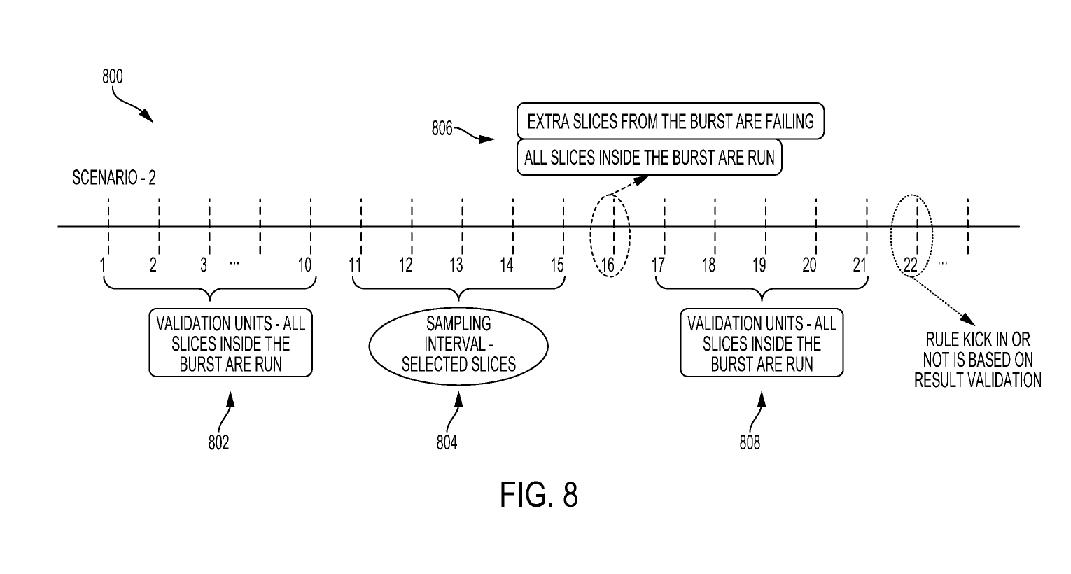

FIG. 8 illustrates modifying the process described above when extra slices from one of the burst intervals are failing. The scenario 800 begins with step 802 when the validation units are tested. The validation units have all slices inside the burst run. Next, in interval 804 a sampling interval samples selected slices. At 806, it is determined that extra slices from the burst are failing. This causes all slices inside the burst to be tested. Next in interval 808, another validation unit occurs and all slices inside the burst are tested. After the additional validation interval, it may be determined whether to have additional tests performed for a period of time to catch failures. This may be referred to as a rule kicking in for the production run, and determining when to activate the rule modulating the sampling rate may also be activated. All steps in both FIGS. 7 and 8 may be performed automatically, with automated test equipment.

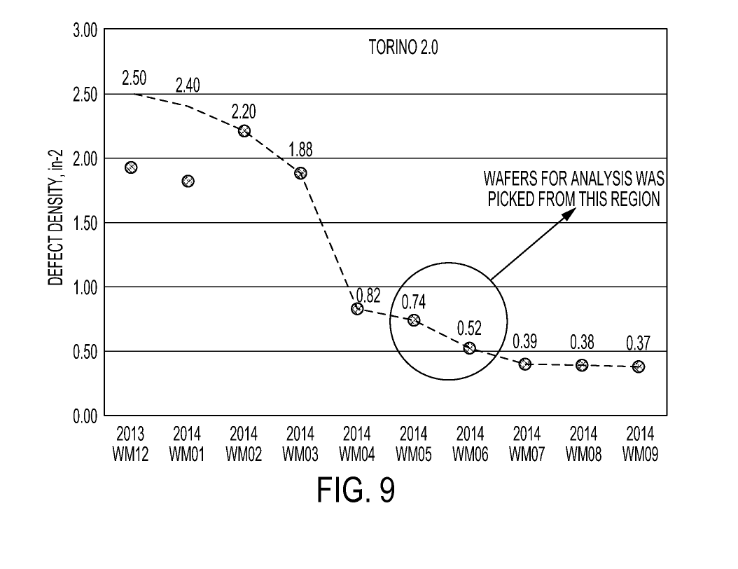

FIG. 9 is a defect density plot for a sample chip device multiple lot production. The first 10 lots provide that an entire set of tests is run vs defect density. The first four lots show the defect density above the required level for a mature manufacturing process. From lots 5 and on the defect density is below the critical threshold for a mature manufacturing process. It is from Lots six and seven that the reduced test analysis is performed. As shown in FIG. 7 steps 11-15 for a minimum run is selected, based on the reduced defect shown in the plot in FIG. 9. In steps 16 and onward, the full testing set may again be run. This embodiment provides highly flexible control and allows for coverage control at any point in the testing process. The specific slices may also be enabled based on voltage level.

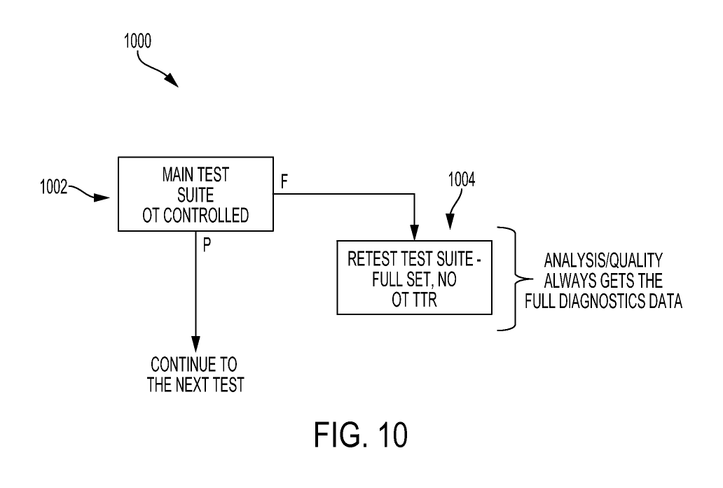

FIG. 10 is a flowchart of a test flow implementation at the wafer sort level. The method 1000 beings with the main test suite operationally controlled in step 1002. Passing wafers process to the next test, as indicated by the P designation. Failing devices at sent to the retest suite at step 1004. In the retest suite the full set of operational tests are run with no test time reduction. At the wafer sort level, two burst vectors are needed for every block name vector on the wafer. One burst vector is selectively used in operational testing to selectively enable the slices to allow test time reduction. The other vector may be used in the retest section of the test suite and may collect an error log. The error log will be used in the event of main test suite failure and loss of data. This ensures that error logs are collected for the entire set instead of the partial set used in the main test. The failure location is mapped back to the failing flip-flop on the chip and gives the location of the failure. Each slice may require subtracting or adding an offset to yield the actual flip-flop location.

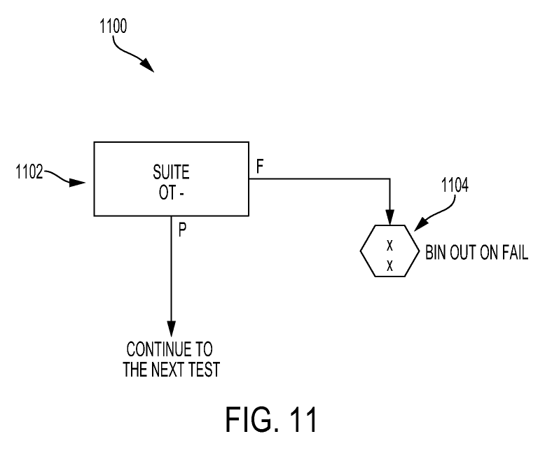

FIG. 11 is a flowchart of a test flow implementation at the final test level. In this instance, only one burst vector is needed for every block name vector. Operational testing operates on the single burst and selectively enables the slices, resulting in test time reduction. Error logs are not collected at final test. A further embodiment allows enabling the complement of the slice set that was run at the wafer sort level. This ensures that the full set of tests is run for all bin 1 dies from the wafer sort testing.

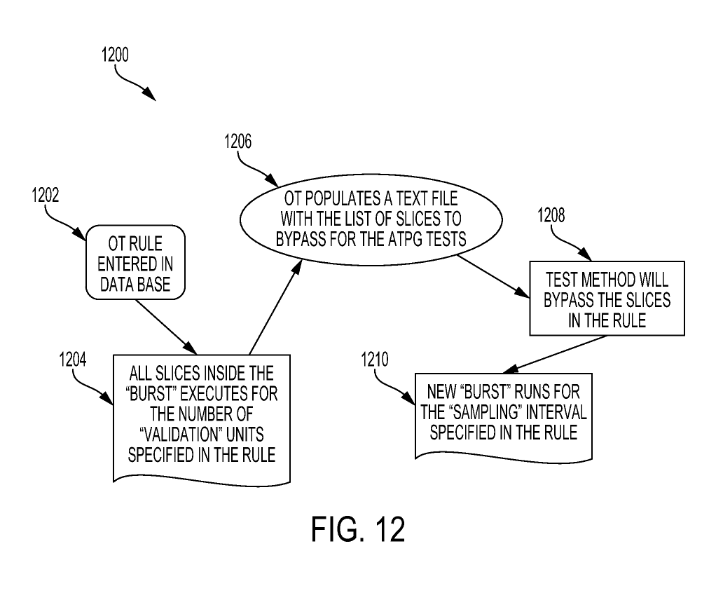

FIG. 12 is a flowchart for adaptive test time reduction. The method 1200 begins when the operational testing rule is entered in a testing database in step 1202. In step 1204, all slices inside the burst are tested for the number of validation units specified in the operational testing rule. Next, in step 1206 the operational tester populates a text file with the list of slices to be bypassed or skipped by the automatic test pattern generation testing. In step 1208, the testing occurs with the test method bypassing the slices in the rule. Finally, in step 1210 new burst test runs are specified based on the sampling interval specified in the operational testing rule.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, circuits, and algorithm steps described in connection with the exemplary embodiments disclosed herein may be implemented as electronic hardware, computer software, or combinations of both. To clearly illustrate this interchangeability of hardware and software, various illustrative components blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the exemplary embodiments of the invention.

The various illustrative logical blocks, modules, and circuits described in connection with the exemplary embodiments disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

In one or more exemplary embodiments, the functions described may be implemented in hardware, software, firmware, or any combination thereof If implemented in software, the functions may be stored on or transmitter over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM EEPROM, CD-ROM or other optical disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

The previous description of the disclosed exemplary embodiments is provided to enable any person skilled in the art to make or use the invention. Various modifications to these exemplary embodiments will be readily apparent to those skilled in the art, and the generic principles defined herein may be applied to other embodiments without departing from the spirit or scope of the invention. Thus, the present invention is not intended to be limited to the exemplary embodiments shown herein but is to be accorded the widest scope consistent with the principles and novel features disclosed herein.

What is claimed is:

1. A method for adaptive test time reduction, comprising:
running a predetermined number of structural tests on multiple production lots of electronic components;
collecting pass/fail data for the predetermined number of structural tests;
determining which of the predetermined structural tests are consistently passed;
grouping the consistently passed structural tests into slices within test vectors;
skipping the consistently passed structural tests when testing future production lots of the electronic components; and
performing only those structural tests that produce failures.

2. The method of claim 1, further comprising:
analyzing the structural test generating failures to identify defects causing rejection of electronic components.

3. The method of claim 1, wherein the electronic device is a wafer.

4. The method of claim 1, wherein the electronic device is an electronic chip at a final testing stage.

5. The method of claim 1, wherein a first test vector is a test setup slice.

6. The method of claim 5, wherein second and subsequent test vectors contain slices of structural tests that produce failures.

7. The method of claim 6, wherein the slices containing structural tests that produce failures are added to a test flow as a burst that calls individual slices.

8. The method of claim 2, wherein the analyzing the structural tests generating failures also determines a minimum number of slices producing the failures.

9. The method of claim 1, further comprising:
performing only those structural tests that produce failures on a production lot of wafers;
determining which wafers pass the structural tests that produce failures; and
performing the structural test that produce failures again as a final test after completing fabrication of electronic chips fabricated from the passing wafers.

10. The method of claim 1, further comprising:
modulating a sampling rate in response to collecting pass/fail data for the predetermined number of structural tests.

11. The method of claim 9, wherein the final test is a complement of the structural tests producing failures in wafers.

12. An apparatus for test time reduction, comprising:
means for running a predetermined number of structural tests on multiple production lots of electronic components;
means for collecting pass/fail data for the predetermined number of structural tests;
means for determining which of the predetermined structural tests are consistently passed;
means for grouping the consistently passed structural tests into slices within test vectors;
means for skipping the consistently passed structural tests when testing future production lots of the electronic components; and
means for performing only those structural tests that produce failures.

13. The apparatus of claim 12, further comprising:
means for analyzing the structural tests generating failures to identify defects causing rejection of the electronic components.

14. The apparatus of claim 13, wherein the means for analyzing the structural tests generating failures also determines a minimum number of slices producing the failures.

15. The apparatus of claim 12, further comprising:
means for performing only those structural tests that produce failures on a production lot of wafers;
means for determining which wafers pass the structural tests that produce failures; and
means for performing the structural test that produce failures again as a final test after completing fabrication of electronic chips fabricated from the passing wafers.

16. The apparatus of claim 12, further comprising:
means for modulating a sampling rate in response to collecting pass/fail data for the predetermined number of structural tests.

17. A non-transitory computer-readable medium containing instructions, which when executed cause a processor to perform the steps of:
running a predetermined number of structural tests on multiple production lots of electronic components;
collecting pass/fail data for the predetermined number of structural tests;
determining which of the predetermined structural tests are consistently passed;
grouping the consistently passed structural tests into slices within test vectors;
skipping the consistently passed structural tests when testing future production lots of the electronic components; and
performing only those structural tests that produce failures.

18. The non-transitory computer-readable medium of claim 17, further comprising instructions for:
analyzing the structural test generating failures to identify defects causing rejection of electronic components.

19. The non-transitory computer-readable medium of claim 18, wherein the analyzing the structural tests generating failures also determines a minimum number of slices producing the failures.

20. The non-transitory computer-readable medium of claim 17, further comprising instructions for:
modulating a sampling rate in response to collecting pass/fail data for the predetermined number of structural tests.
